(19) United States
(12) Patent Application Publication
(10) Pub. No.: US 2023/0081392 A1
(43) Pub. Date: Mar. 16, 2023

(54) INTELLIGENT POWER DISTRIBUTION DEVICE

(71) Applicants: State Grid Jiangsu Electric Power Co., Ltd. Nanjing Power Supply Company, Nanjing (CN); Nanjing Jointest Information System Co., Ltd., Nanjing (CN)

(72) Inventors: Hong Zhu, Nanjing (CN); Shaojun Liu, Nanjing (CN); Xiaohong Kong, Nanjing (CN); Min Lu, Nanjing (CN); Jingwei Li, Nanjing (CN); Bo Wang, Nanjing (CN); Dianxin Chen, Nanjing (CN); Tiancheng Zhao, Nanjing (CN); Linqing Yang, Nanjing (CN); Xing Su, Nanjing (CN); Shumin Chen, Nanjing (CN)

(21) Appl. No.: 17/453,209

(22) Filed: Nov. 2, 2021

(30) Foreign Application Priority Data
Sep. 14, 2021 (CN) 202111071702.5

(51) Int. Cl. G01R 31/08; H02J 13/00; G01R 19/165; G01R 31/52

(52) U.S. Cl. CPC G01R 31/086; H02J 13/00002; G01R 19/16571; G01R 31/52; H02H 7/26

(57) ABSTRACT

An intelligent power distribution device is provided, which includes a power distribution diagnosis module and a power distribution monitoring module. The power distribution monitoring module includes a power measuring and controlling instrument. The power measuring and controlling instrument is configured to connect to a power supply line to be protected, and measure power data of the power supply line. The power distribution diagnosis module is connected to the power measuring and controlling instrument, and is configured to analyze the power data uploaded by the power measuring and controlling instrument, and protect the power supply line when it is determined based on an analysis result that the power supply line requires protection. Based on the analysis result of the power data of the power supply line, the intelligent power distribution device can protect the power supply line precisely and accurately, thereby improving protection effect of the power supply line.

### CROSS-REFERENCE TO RELATED APPLICATIONS

The present application claims priority to Chinese Patent Application No. CN 202111071702.5 filed on Sep. 14, 2021 which is hereby incorporated by reference as though fully set forth herein.

### FIELD

The present disclosure relates to the technical field of electric power monitoring, and in particular to an intelligent power distribution device.

### BACKGROUND

Since the generation of sustainable electricity by generators, mankind actually has demands to manage and control electricity. The history of mankind enjoying light and happiness brought by electricity is also the history of panic and fear of electricity and struggling with electricity. Because of accidents and fires resulted from electricity, mankind has paid with hundreds of millions of lives and incalculable property.

In modern times, daily life is inseparable from electricity. However, how to better protect lives under threat of electricity, and how to use electricity more economically and safely are problems required to be solved by researchers. At present, an air switch is added to a power supply line to improve safety of the power supply line, which has relatively single protection effect and limited function.

### SUMMARY

In order to solve the above problems, an intelligent power distribution device is provided according to embodiments of the present disclosure.

An intelligent power distribution device is provided according to an embodiment of the present disclosure. The intelligent power distribution device includes a power distribution diagnosis module and a power distribution monitoring module. The power distribution monitoring module includes a power measuring and controlling instrument.

The power measuring and controlling instrument is configured to connect to a power supply line to be protected, and measure power data of the power supply line. The power data includes a current, a voltage, and one or more of active power, reactive power, apparent power, a power factor, a power supply frequency, a peak voltage, a peak current, and power harmonics.

The power distribution diagnosis module is connected to the power measuring and controlling instrument, and is configured to analyze the power data uploaded by the power measuring and controlling instrument, and protect the power supply line when it is determined based on an analysis result that the power supply line requires protection.

In an embodiment, the power distribution diagnosis module includes a wireless communication unit. The wireless communication unit is configured to: upload the power data to a cloud platform; instruct the cloud platform to iteratively update, based on the power data uploaded by the wireless communication unit, a data operating characteristic database; and receive the updated data operating characteristic database transmitted by the cloud platform.

The power distribution diagnosis module is configured to analyze the power data uploaded by the power measuring and controlling instrument, including: matching the power data with the locally stored data operating characteristic database, to determine whether the power data is abnormal.

In an embodiment, the power distribution monitoring module further includes one or more of a leakage protector, a lightning protector, and an air switch.

The leakage protector is configured to connect to the power supply line, and determine whether the power supply line is leaking based on a unbalanced current between a phase line and a neutral line of the power supply line, act when the power supply line is leaking, and transmit a leakage signal to the power distribution diagnosis module.

The lightning protector is configured to connect to the power supply line, act when a surge voltage of the power supply line exceeds a preset voltage, and transmit a surge signal to the power distribution diagnosis module.

The air switch is configured to connect to the power supply line, act when a current flowing through the power supply line exceeds a preset current, and transmit an overcurrent signal to the power distribution diagnosis module.

In an embodiment, the intelligent power distribution device further includes a mounting frame, a first guide rail and a second guide rail. Both the first guide rail and the second guide rail are arranged on the mounting frame.

The power distribution diagnosis module is arranged on the first guide rail. The power distribution monitoring module is arranged on the second guide rail.

In an embodiment, the intelligent power distribution device further includes a fixing mechanism. The fixing mechanism is arranged on a back of the power distribution diagnosis module and is configured to fix the power distribution diagnosis module on the first guide rail.

In an embodiment, the fixing mechanism includes a mechanism body, a fixed clamping piece, and a movable clamping piece. The mechanism body is arranged on the back of the power distribution diagnosis module. The fixed clamping piece and the movable clamping piece are both arranged on a side of the mechanism body that is remote from the power distribution diagnosis module. Both the fixed clamping piece and the movable clamping piece are arranged along the length direction of the first guide rail.

In an embodiment, the movable clamping piece is configured to move back and forth between a first position and a second position. In a case that the movable clamping piece is at the first position, a distance between the movable clamping piece and the fixed clamping piece is not less than a width of the first guide rail. In a case that the movable clamping piece is at the second position, a distance between the movable clamping piece and the fixed clamping piece is smaller than the width of the first guide rail, where the movable clamping piece bears force along a width direction of the first guide rail and remains motionless.

In an embodiment, the fixing mechanism further includes a guide rod, an elastic member, a connection block, and a sliding block.

The mechanism body includes a first limiting part and a second limiting part that are arranged along the length direction of the first guide rail. A cavity structure is formed between the first limiting part and the second limiting part. A first slot is formed on a side of the mechanism body remote from the power distribution diagnosis module. The first slot is in communication with the cavity structure. The second limiting part is provided with a second slot through which the cavity structure is in communication with the outside of the mechanism body.

The movable clamping piece is provided with an extension part passing through the first slot. The extension part is moveable in the first slot along the width direction of the first guide rail. The extension part is provided with a through hole along the width direction of the first guide rail, and the through hole is arranged in the cavity structure.

The guide rod is arranged between the first limiting part and the second limiting part, and passes through the through hole. The elastic member is arranged along the guide rod and between the first limiting part and the extension part.

The connection block is arranged in the cavity structure and is fixed to the extension part. A side of the connection block close to the second slot has a first boss structure with a first inclined surface.

The sliding block is arranged in the second slot and is configured to slide, in the second slot, back and forth between a third position and the fourth position along a direction perpendicular to the width direction of the first guide rail. A side of the sliding block close to the connection block has a second boss structure with a second inclined surface. The first inclined surface fits the second inclined surface. The first inclined surface and the second inclined surface slope with respect to the direction along which the sliding block slide.

In a case that the sliding block is at the third position, an end of the first boss structure is at bottom of the second boss structure, and the movable clamping piece is at the first position. In a case that the sliding block is at the fourth position, the end of the first boss structure is located on top of the second boss structure and is attached to the top of the second boss structure, and the movable clamping piece is at the second position.

In an embodiment, the number of the guide rod, the number of the elastic member and the number of the through hole each are more than one and are equal. The more than one guide rod, the more than one elastic member, and the more than one through hole are distributed along the length direction of the first guide rail.

In an embodiment, the fixing mechanism further includes a dial block. The dial block is fixedly connected to the sliding block, and at least part of the dial block protrudes from the mechanism body.

In an embodiment, the number of the fixing mechanism is more than one, and the more than one fixing mechanism is arranged on the back of the power distribution diagnosis module along a length direction of the first guide rail.

In the above technical solutions according to embodiments of the present disclosure, the power measuring and controlling instrument transmits the acquired power data of the power supply line to the power distribution diagnosis module. The power distribution diagnosis module analyzes the power data to determine whether to protect the power supply line and perform corresponding operations. Based on the analysis result of the power data of the power supply line, the intelligent power distribution device can protect the power supply line precisely and accurately, thereby improving protection effect of the power supply line.

In order to make the above objectives, features and advantages of the present disclosure more comprehensible, preferred embodiments accompanied with accompanying drawings are described in detail below.

### BRIEF DESCRIPTION OF THE DRAWINGS

In order to more clearly illustrate technical solutions in embodiments of the present disclosure or in the conventional technology, the drawings to be used in the description of the embodiments or the conventional technology are briefly described below. Apparently, the drawings in the following description show only some embodiments of the present disclosure, and other drawings may be obtained by those skilled in the art from the drawings without any creative work.

FIG. 1 is a schematic structural diagram showing an intelligent power distribution device according to an embodiment of the present disclosure;

FIG. 2 is a schematic structural diagram showing an intelligent power distribution device according to another embodiment of the present disclosure;

FIG. 3 shows a perspective view of the intelligent power distribution device according to an embodiment of the present disclosure;

FIG. 4 shows a perspective view of a part of a structure of the intelligent power distribution device according to an embodiment of the present disclosure;

FIG. 5 is a schematic diagram showing a manner for fixing a power distribution diagnosis module in the intelligent power distribution device according to an embodiment of the present disclosure;

FIG. 6 shows a front view of a fixing mechanism according to an embodiment of the present disclosure;

FIG. 7 shows a rear cross-sectional view of the fixing mechanism according to an embodiment of the present disclosure; and

FIG. 8 shows a rear cross-sectional view of the fixing mechanism according to another embodiment of the present disclosure.

### REFERENCE SIGNS

10 power distribution diagnosis module,
11 wireless communication unit,
12 display screen,
13 button,
20 power distribution monitoring module,
21 power measuring and controlling instrument,
22 leakage protector,
23 lightning protector,
24 air switch,
30 mounting frame,
40 first guide rail,
50 second guide rail,
60 fixing mechanism,
61 mechanism body,
611 first limiting part,
612 second limiting part,
613 cavity structure,
614 first slot,
615 second slot,
62 fixed clamping piece,
63 movable clamping piece,
631 extension part,
64 guide rod,
65 elastic member,
66 connection block,
661 first inclined surface,
67 sliding block,
671 second inclined surface,
68 dial block,
100 cloud platform.

### DETAILED DESCRIPTION OF EMBODIMENTS

In the description of the present disclosure, it should be understood that orientation or positional relationships indicated by terms such as “center”, “vertical”, “horizontal”, “length”, “width”, “thickness”, “upper”, “lower”, “front”, “rear”, “left”, “right”, “upright”, “level”, “top”, “bottom”, “inside”, “outside”, “clockwise”, “counterclockwise” are based on the drawings, are only for the convenience of describing the present disclosure and simplifying the description, rather than indicating or implying that the indicated device or element must have a specific orientation, or be constructed or operated in a specific orientation, and therefore cannot be construed as a limitation to the present disclosure.

In addition, terms such as “first” and “second” are only used for illustration, and should not be understood as indicating or implying relative importance or implicitly indicating the number of indicated technical features. Therefore, features defined with “first” and “second” may explicitly or implicitly include one or more of these features. In the description of the present disclosure, “multiple or a plurality of” means two or more than two, unless specifically defined otherwise.

In the present disclosure, unless otherwise clearly specified and limited, terms such as “mounted”, “connected with”, “connected to”, “fixed” should be understood in a broad sense, for example, a fixed connection, a detachable connection, an integral connection, a mechanical connection, an electrical connection, a direct connection, an indirect connection via an intermediate medium, or internal communication between two components. For those skilled in the art, meaning of the above terms in the present disclosure should be understood depending on specific situations.

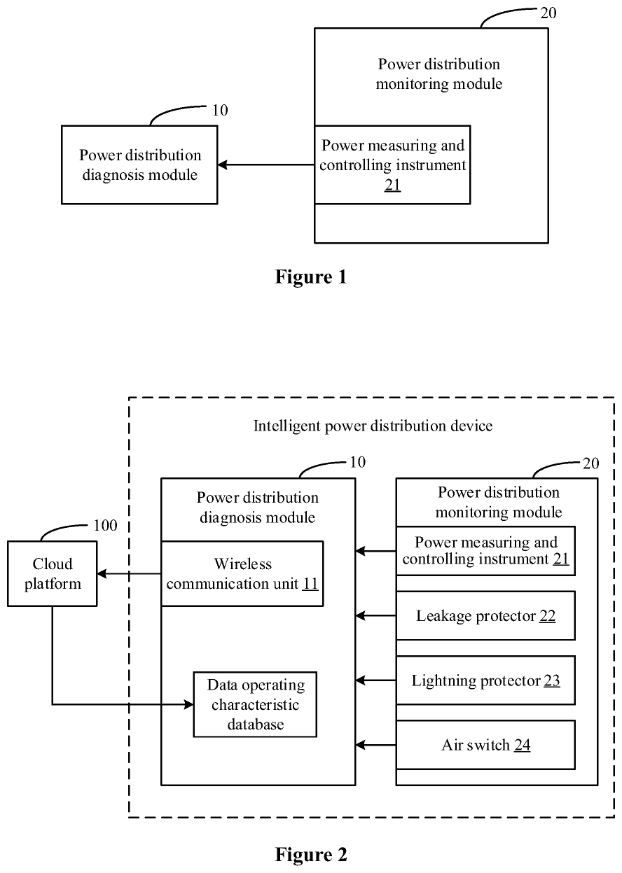

An intelligent power distribution device is provided according to an embodiment of the present disclosure. As shown in FIG. 1, the intelligent power distribution device includes a power distribution diagnosis module 10 and a power distribution monitoring module 20. The power distribution monitoring module 20 includes a power measuring and controlling instrument 21.

The power measuring and controlling instrument 21 is configured to connect to a power supply line to be protected, and measure power data of the power supply line. The power data includes a current, a voltage, and further includes one or more of active power, reactive power, apparent power, a power factor, a power supply frequency, a peak voltage, a peak current, and power harmonics. The power distribution diagnosis module 10 is connected to the power measuring and controlling instrument 21, and is configured to analyze the power data uploaded by the power measuring and controlling instrument 21, and protect the power supply line when it is determined based on an analysis result that the power supply line requires protection.

In the embodiment of the present disclosure, the power measuring and controlling instrument 21 is connected to the power supply line to be protected, for example, in series or parallel with the power supply line, so as to acquire power data such as the voltage and the current of the power supply line, and transmit the power data to the power distribution diagnosis module 10. The power distribution diagnosis module 10 is capable of data processing. After acquiring the power data of the power supply line, the power distribution diagnosis module 10 analyzes the power data to determine whether the power data is abnormal. If the power data is abnormal, it indicates that an operation state of the power supply line is abnormal. In this case, the power supply line is protected, for example, the power supply line is cut off, or a current flowing through the power supply line is limited when the current is too large. In addition, the power data further includes active power, reactive power, apparent power, a power factor, a power supply frequency, a peak voltage, a peak current, power harmonics or the like, so that the power distribution diagnosis module 10 can analyze the operation state of the power supply line more completely and accurately.

In the intelligent power distribution device according to the embodiment of the present disclosure, the power measuring and controlling instrument 21 transmits the acquired power data of the power supply line to the power distribution diagnosis module 10. The power distribution diagnosis module 10 analyzes the power data, so as to determine whether to protect the power supply line, and perform corresponding operations. Based on the analysis result of the power data of the power supply line, the intelligent power distribution device can protect the power supply line precisely and accurately, thereby improving protection effect of the power supply line.

In an embodiment, referring to FIG. 2, the power distribution diagnosis module 10 includes a wireless communication unit 11. The wireless communication unit 11 is configured to upload the power data to a cloud platform 100 and instruct the cloud platform 100 to iteratively update, based on the power data uploaded by the wireless communication unit 11, a data operating characteristic database. The wireless communication unit 11 is further configured to receive the updated data operating characteristic database transmitted by the cloud platform 100. The power distribution diagnosis module 10 analyzes the power data uploaded by the power measuring and controlling instrument 21, including: matching the power data with a locally stored data operating characteristic database, to determine whether the power data is abnormal.

In the embodiment of the present disclosure, the power distribution diagnosis module 10 is capable of wireless communication, and uploads the power data to the cloud platform 100 based on the wireless communication unit 11. The cloud platform 100 may be connected to multiple intelligent power distribution devices, thereby comprehensively processing power data uploaded by the multiple intelligent power distribution devices. The cloud platform 100 performs comprehensive analysis based on technologies such as big data and artificial intelligence, to extract operating characteristics based on the power data, so as to generate an operating characteristics database. The cloud platform 100 may generate respective data operating characteristics databases for the multiple intelligent power distribution devices, or generate one data operating characteristics database for the multiple intelligent power distribution devices, which is not limited in this embodiment. In addition, the cloud platform 100 may periodically receive power data, thereby periodically updating the data operating characteristic database, and sending the updated data operating characteristic database to the power distribution diagnosis module 10 of the intelligent power distribution device.

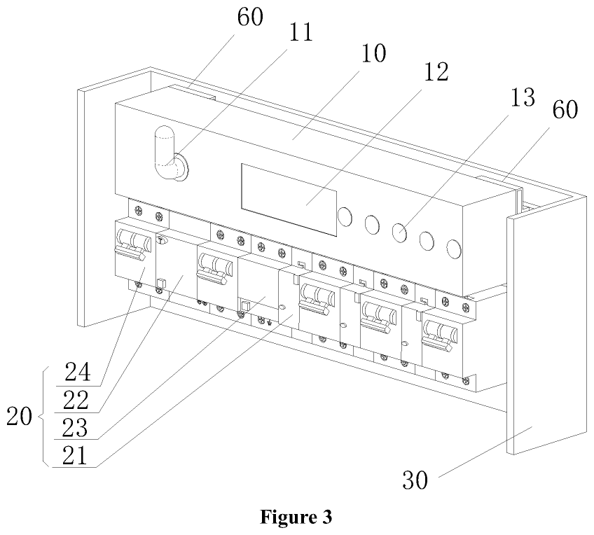

The power distribution diagnosis module 10 updates the local data operating characteristic database based on the data operating characteristic database (including a complete characteristic database or only the updated part) transmitted by the cloud platform 100, and compares the local data operating characteristic database with the acquired power data, so as to accurately determine the current state of the power supply line. For example, a power supply line that has abnormality or potential hazards and thus affects safe operation is forcibly cut off. Alternatively, a power supply line that is currently out of danger is supplied with electricity in time. In addition, the cloud platform 100 or the wireless communication unit 11 communicates with a user terminal, so that the user can view the operation state of the power supply line in real time. Alternatively, the cloud platform 100 or the wireless communication unit 11 receives a control instruction transmitted by a user terminal and responds to the control instruction, so as to monitor and control the intelligent power distribution device. As shown in FIG. 3, the wireless communication unit 11 is provided with an antenna, so as to increase power when transmitting and receiving data.

In addition, referring to FIGS. 2 and 3, the power distribution monitoring module 20 further includes one or more of a leakage protector 22, a lightning protector 23, and an air switch 24. The leakage protector 22 is configured to connect to the power supply line, determine whether the power supply line is leaking based on a unbalanced current between a phase line and a neutral line of the power supply line, act (for example, cut off the power supply line) when the power supply line is leaking, and transmit a leakage signal to the power distribution diagnosis module 10. The lightning protector 23 is configured to connect to the power supply line, act (for example, cut off the power supply line) when a surge voltage of the power supply line exceeds a preset voltage, and transmit a surge signal to the power distribution diagnosis module 10. The air switch 24 is configured to connect to the power supply line, act (for example, cut off the power supply line) when a current flowing through the power supply line exceeds a preset current, and transmit an overcurrent signal to the power distribution diagnosis module 10. The leakage protector 22, the lightning protector 23, and the air switch 24 in the embodiments of the present disclosure can perform leakage protection, lightning protection and the like, thereby further improving safety of the intelligent power distribution device.

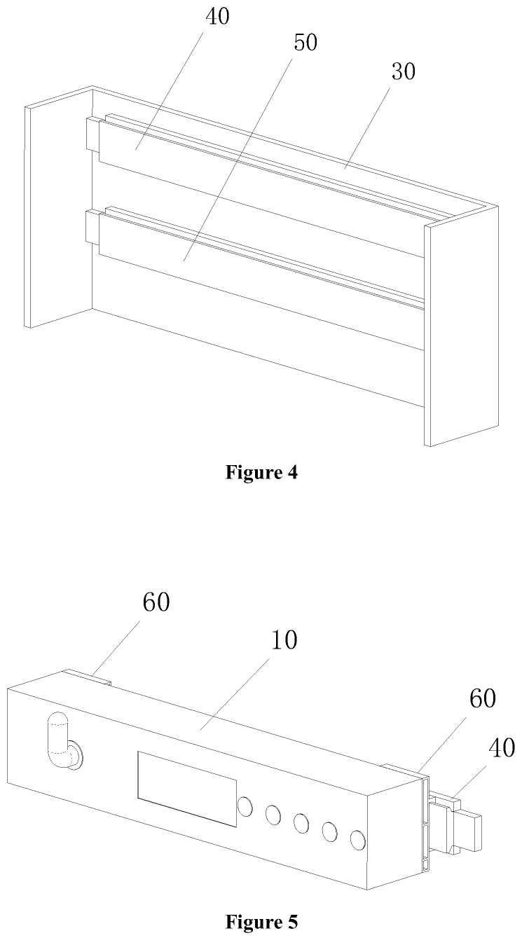

On the basis of the above embodiment, referring to FIGS. 3 and 4, the intelligent power distribution device further includes a mounting frame 30, a first guide rail 40 and a second guide rail 50. Both the first guide rail 40 and the second guide rail 50 are arranged on the mounting frame 30. The power distribution diagnosis module 10 is arranged on the first guide rail 40. The power distribution monitoring module 20 is arranged on the second guide rail 50.

In the embodiment of the present disclosure, the power distribution diagnosis module 10 and the power distribution monitoring module 20 are conveniently arranged on the guide rails (namely, the first guide rail 40 and the second guide rail 50). Moreover, since the power distribution monitoring module 20 may include multiple or various devices, these devices may be evenly distributed. The first guide rail 40 and the second guide rail 50 are two separate guide rails, as shown in FIG. 4. Alternatively, the first guide rail 40 and the second guide rail 50 are integrally formed. For example, the first guide rail 40 and the second guide rail 50 are implemented by one guide rail. The specific form of the first guide rail 40 and the second guide rail 50 is not limited in this embodiment.

In an embodiment of the present disclosure, the power distribution diagnosis module 10 is fixed by a fixing mechanism 60. As shown in FIGS. 3 and 5, the intelligent power distribution device further includes a fixing mechanism 60. The fixing mechanism 60 is arranged on a back of the power distribution diagnosis module 10 and is configured to fix the power distribution diagnosis module 10 on the first guide rail 40.

The power distribution diagnosis module 10 has a certain length. In particular, the power distribution diagnosis module 10 may be provided with other functions, which results in a longer length of the power distribution diagnosis module 10. As shown in FIG. 3, the power distribution diagnosis module 10 is further provided with a display screen 12 and multiple buttons 13 and the like, to achieve corresponding functions. In order to fix the power distribution diagnosis module 10 stably, multiple fixing mechanism 60 may be provided. The multiple fixing mechanisms 60 are arranged on the back of the power distribution diagnosis module 10 along a length direction of the first guide rail 40.

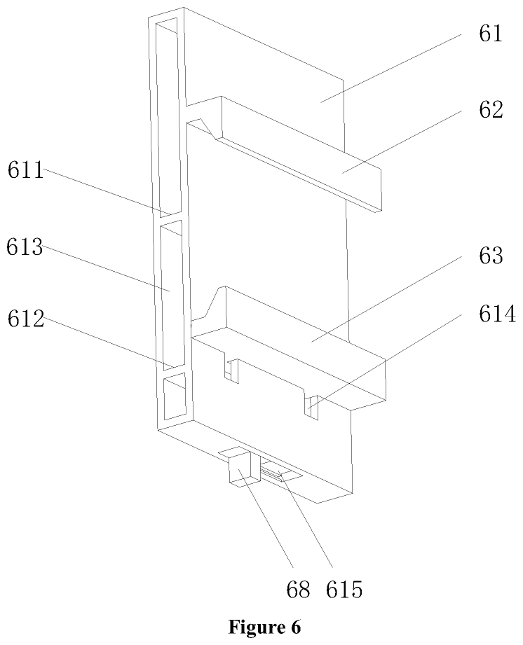

In addition, in an embodiment of the present disclosure, the fixing mechanism 60 includes a mechanism body 61, a fixed clamping piece 62, and a movable clamping piece 63 so as to quickly and securely fix the power distribution diagnosis module 10 on the first guide rail 40, as shown in FIG. 6. The mechanism body 61 is arranged on the back of the power distribution diagnosis module 10. The fixed clamping piece 62 and the movable clamping piece 63 are both arranged on a side of the mechanism body 61 that is remote from the power distribution diagnosis module 10. Both the fixed clamping piece 62 and the movable clamping piece 63 are arranged along the length direction of the first guide rail 40.

The movable clamping piece 63 is configured to move back and forth between a first position and a second position. When the movable clamping piece 63 is at the first position, a distance between the movable clamping piece 63 and the fixed clamping piece 62 is not less than a width of the first guide rail 40. When the movable clamping piece 63 is at the second position, the distance between the movable clamping piece 63 and the fixed clamping piece 62 is smaller than the width of the first guide rail 40, where the movable clamping piece 63 can bear force along a width direction of the first guide rail 40 and remain motionless.

In the embodiment of the present disclosure, a main structure of the fixing mechanism 60 is referred to as the mechanism body 61. A side of the mechanism body 61 has a flat surface, and is attached to the back of the power distribution diagnosis module 10, for example, fixed on the back of the power distribution diagnosis module 10 by a bolt or pasted on the back of the power distribution diagnosis module 10. The fixed clamping piece 62 and the movable clamping piece 63 are arranged on another side of the mechanism body 61 and protrude from the side of the mechanism body 61. The first guide rail 40 is clamped between the two clamping pieces (namely, the fixed clamping piece 62 and the movable clamping piece 63), thereby fixing the power distribution diagnosis module 10 on the first guide rail 40.

The first guide rail 40 is generally in a long strip structure with a length direction (that is, a horizontal direction in FIG. 4) and a width direction (that is, a vertical direction in FIG. 4). The two clamping pieces are arranged along the length direction, and the movable clamping piece 63 is capable of reciprocating between the first position and the second position along the width direction. As shown in FIG. 6, the movable clamping piece 63 is capable of moving up and down. When the movable clamping piece 63 is at the first position, for example, a lower position, a distance between the movable clamping piece 63 and the fixed clamping piece 62 is relatively large, and is not less than the width of the first guide rail 40, so as to arrange the first guide rail 40 between the fixed clamping piece 62 and the movable clamping piece 63. When the movable clamping piece 63 is at the second position, for example, an upper position, a distance between the movable clamping piece 63 and the fixed clamping piece 62 is relatively small, and is smaller than the width of the first guide rail 40, so that the first guide rail 40 is clamped between the movable clamping piece 63 and the fixed clamping piece 62, thereby fixing the power distribution diagnosis module 10.

The movable clamping piece 63 remains motionless at the second position. For example, when receiving a force along the width direction of the first guide rail 40, the movable clamping piece 63 is still at the second position, so as to prevent the movable clamping piece 63 from loosening from the first guide rail 40.

In the embodiment of the present disclosure, the movable clamping piece 63 and the fixed clamping piece 62 are bent toward each other. As shown in FIG. 6, the movable clamping piece 63 and the fixed clamping piece 62 are each L-shaped and bent toward each other. The “distance between the movable clamping piece 63 and the fixed clamping piece 62” in this embodiment refers to a minimum distance between the movable clamping piece 63 and the fixed clamping piece 62. When the movable clamping piece 63 is in the second position, a maximum distance between the movable clamping piece 63 and the fixed clamping piece 62 may be greater than or equal to the width of the first rail 40, so that the first guide rail 40 is clamped between the fixed clamping piece 62 and the fixed clamping piece 62.

In an embodiment of the present disclosure, a cavity structure 613 is formed inside the mechanism body 61. A part of the movable clamping piece 63 (that is, the extension part 631) is arranged in the cavity structure 613. A position of the extension part 631 in the cavity structure 613 is adjusted by a linkage mechanism in the mechanism body 61, so as to conveniently change the position of the movable clamping piece 63. In this way, the movable clamping piece 63 moves back and forth between the first position and the second position. Referring to FIGS. 6 to 8, the fixing mechanism 60 further includes a guide rod 64, an elastic member 65 (e.g., a spring), a connection block 66 and a sliding block 67.

The mechanism body 61 includes a first limiting part 611 and a second limiting part 612 that are arranged along the length direction of the first guide rail 40. The cavity structure 613 is formed between the first limiting part 611 and the second limiting part 612. A first slot 614 is formed on a side of the mechanism body 61 remote from the power distribution diagnosis module 10. The first slot 614 is in communication with the cavity structure 613. The second limiting part 612 is provided with a second slot 615 through which the cavity structure 613 is in communication with the outside of the mechanism body 61. The movable clamping piece 63 is provided with an extension part 631 passing through the first slot 614. The extension part 631 is moveable in the first slot 614 along the width direction of the first guide rail 40. The extension part 631 is provided with a through hole along the width direction of the first guide rail 40, and the through hole is located in the cavity structure 613. The guide rod 64 is arranged between the first limiting part 611 and the second limiting part 612, and passes through the through hole. The elastic member 65 is arranged along the guide rod 64 and between the first limiting part 611 and the extension part 631. The connection block 66 is arranged in the cavity structure 613 and is fixed to the extension part 631. A side of the connection block 66 close to the second slot 615 has a first boss structure with a first inclined surface 661. The sliding block 67 is arranged in the second slot 615 and is configured to slide, in the second slot 615, back and forth between a third position and the fourth position along a direction perpendicular to the width direction of the first guide rail 40. A side of the sliding block 67 close to the connection block 66 has a second boss structure with a second inclined surface 671. The first inclined surface 661 fits the second inclined surface 671. The first inclined surface 661 and the second inclined surface 671 slope with respect to the direction along which the sliding block 67 slides. In a case that the sliding block 67 is at the third position, an end of the first boss structure is at bottom of the second boss structure, and the movable clamping piece 63 is at the first position. In a case that the sliding block 67 is at the fourth position, the end of the first boss structure is located on top of the second boss structure and is attached to the top of the second boss structure, and the movable clamping piece 63 is at the second position.

In the embodiment of the present disclosure, the mechanism body 61 is provided with the first limiting part 611 and the second limiting part 612, and the cavity structure 613 is formed between the first limiting part 611 and the second limiting part 612. FIG. 6 and the like show an example in which that the first limiting part 611 and the second limiting part 612 are plate-shaped. On the mechanism body 61, the first slot 614 is formed between the first limiting part 611 and the second limiting part 612, so that the extension part 631 of the movable clamping piece 63 passes through the first slot 614 to enter the cavity structure 613. The extension part 631 is provided with a through hole along the width direction of the first guide rail 40. The guide rod 64 passes through the through hole, so that the extension part 631 and the movable clamping piece 63 move along the width direction of the first guide rail 40 as a whole. In this way, the movable clamping piece 63 easily moves back and forth between the first position and the second position.

When moving to the fixed clamping piece 62 (that is, from the first position to the second position), the movable clamping piece 63 moves toward the first limiting part 611. That is, a distance between the movable clamping piece 63 and the first limiting part 611 is gradually reduced. The second limiting part 612 is close to a side of the mechanism body 61. As shown in FIG. 6, the second limiting part 612 is close to the bottom of the mechanism body 61, so that the second slot 615 is conveniently formed on the second limiting part 612. In addition, the sliding block 67 is arranged in the second slot 615, and a position of the connection block 66 is changed by the sliding block 67, thereby changing the position of the extension part 631 fixed to the connection block 66.

In an embodiment of the present disclosure, the fixing mechanism 60 operates as follows.

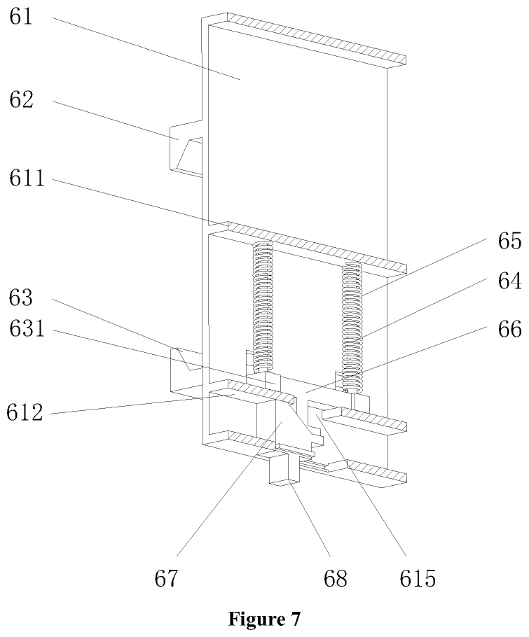

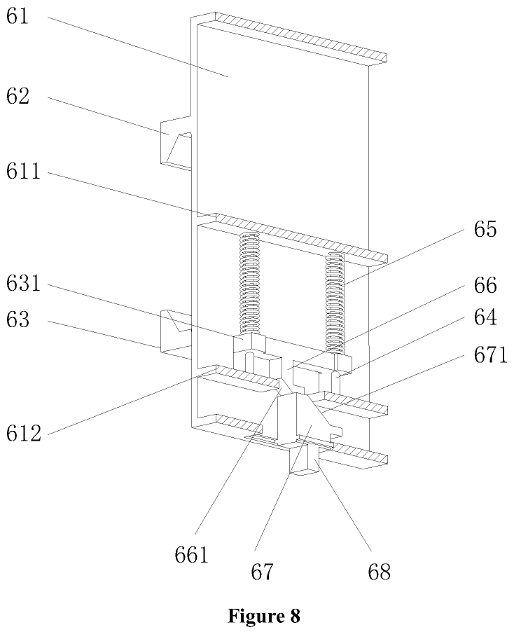

Initially, the sliding block 67 is at a certain position in the second slot 615 (that is, the third position). For example, the sliding block 67 is located on a left side in FIG. 7. The second inclined surface 671 of the sliding block 67 is attached to the first inclined surface 661 of the connection block 66. The extension part 631 is away from the fixed clamping piece 62 due to the elastic member 65. That is, the movable clamping piece 63 is at the first position. Then, the sliding block 67 slides in a direction perpendicular to the width direction of the first guide rail 40. That is, the direction that the sliding block 67 slides is perpendicular to the width direction. In FIGS. 7 and 8, the sliding block 67 slides along a left-right direction. Since the connection block 66 is restricted to only move along the guide rod 64 (that is, the width direction of the first guide rail 40), the second inclined surface 671 is always in contact with the first inclined surface 661 when sliding the sliding block 67, so that the sliding of the sliding block 67 is converted into movement of the connection block 66. As shown in FIGS. 7 and 8, the sliding block 67 slides to the right, and the connection block 66 gradually moves upward, so that the movable clamping piece 63 gradually moves upward, that is, gradually moves from the first position to the second position.

In addition, the sliding block 67 and the connecting block 66 have boss structures (that is, the first boss structure and the second boss structure) that fit each other. When ending the sliding, the sliding block 67 is in the fourth position. For example, as shown in FIG. 8, the sliding block 67 is on the right side of the second slot 615. In this case, surfaces of the two boss structures are attached, that is, the end of the first boss structure is attached to the top of the second boss structure. The surfaces of the two boss structures are perpendicular to the width direction of the first guide rail 40, so that the sliding block 67 and the connection block 66 cannot slide relative to each other even when the movable clamping piece 63 receives a force in the width direction, thereby fixing the movable clamping piece 63 at the second position, and further fixing the power distribution diagnosis module 10 on the first guide rail 40. In order to disassemble the power distribution diagnosis module 10, the sliding block 67 is slid in an opposite direction, which is not described in detail in this embodiment.

In order to facilitate the sliding of the sliding block 67, referring to FIGS. 6 to 8, the fixing mechanism 60 further includes a dial block 68. The dial block 68 is fixedly connected to the sliding block 67, and at least part of the dial block 68 protrudes from the mechanism body 61. For assembly or disassembly, the part of the dial block 68 protruding from the mechanism body 61 is directly moved, thereby achieving assembly and disassembly conveniently and effortlessly.

In an embodiment, there are provided with multiple guide rods 64, multiple elastic members 65, and multiple through holes, and the number of the guide rods 64, the number of the elastic members 65 and the number of the through holes are equal. The multiple guide rods 64, the multiple elastic member 65 and the multiple through holes are distributed along the length direction of the first guide rail 40. FIGS. 7 and 8 show two guide rods 64, two elastic members 65 and two through holes, as an example. By arranging multiple guide rods 64 in the length direction, the moving directions of the extension part 631 and the connection block 66 can be better constrained, so that a linkage process inside the fixing mechanism 60 is stable.

With the intelligent power distribution device according to the embodiments of the present disclosure, the power measuring and controlling instrument 21 transmits the acquired power data of the power supply line to the power distribution diagnosis module 10. The power distribution diagnosis module 10 analyzes the power data to determine whether to protect the power supply line, and performs corresponding operations. Based on the analysis result of the power data of the power supply line, the intelligent power distribution device can protect the power supply line precisely and accurately, thereby improving protection effect of the power supply line. The distance between the movable clamping piece 63 and the fixed clamping piece 62 is adjustable, so that the first guide rail 40 is easily clamped. With the linkage structure inside the cavity structure 613, the position of the movable clamping piece 63 is easily changed by sliding the sliding block 67. In addition, the movable clamping piece 63 can be fixed at the second position, so that the power distribution diagnosis module 10 is stably fixed on the first guide rail 40.

Embodiments of the present disclosure are described above. However, the protection scope of the present disclosure is not limited thereto. Those skilled in the art, within the technical scope disclosed in the present disclosure, can easily conceive of changes or replacement technical solutions, which should be covered by the protection scope of the present disclosure. Therefore, the protection scope of the present disclosure should be subject to the protection scope of the claims.

1. An intelligent power distribution device, comprising:
a power distribution diagnosis module (10);
a power distribution monitoring module (20);
a mounting frame (30);
a first guide rail (40);
a second guide rail (50); and
a fixing mechanism (60), wherein:
the first guide rail (40) and the second guide rail (50) are both arranged on the mounting frame (30); and
the power distribution monitoring module (20) comprises a power measuring and controlling instrument (21), wherein:
the power measuring and controlling instrument (21) is configured to connect to a power supply line to be protected, and measure power data of the power supply line, wherein the power data comprises a current, a voltage, and one or more of active power, reactive power, apparent power, a power factor, a power supply frequency, a peak voltage, a peak current, and power harmonics;
the power distribution diagnosis module (10) is connected to the power measuring and controlling instrument (21), and is configured to analyze the power data uploaded by the power measuring and controlling instrument (21), and protect the power supply line when it is determined based on an analysis result that the power supply line requires protection;
the power distribution diagnosis module (10) is arranged on the first guide rail (40), and the power distribution monitoring module (20) is arranged on the second guide rail (50); and
the fixing mechanism (60) is arranged on a back of the power distribution diagnosis module (10), and is configured to fix the power distribution diagnosis module (10) on the first guide rail (40).

2. The intelligent power distribution device according to claim 1, wherein the power distribution diagnosis module (10) comprises a wireless communication unit (11), wherein
the wireless communication unit (11) is configured to: upload the power data to a cloud platform (100); instruct the cloud platform (100) to iteratively update, based on the power data uploaded by the wireless communication unit (11), a data operating characteristic database; and receive the updated data operating characteristic database transmitted by the cloud platform (100); and
for analyzing the power data uploaded by the power measuring and controlling instrument (21), the power distribution diagnosis module (10) is configured to match the power data with a locally stored data operating characteristic database, to determine whether the power data is abnormal.

3. The intelligent power distribution device according to claim 1, wherein the power distribution monitoring module (20) further comprises one or more of a leakage protector (22), a lightning protector (23) and an air switch (24), wherein:
the leakage protector (22) is configured to connect to the power supply line, and determine whether the power supply line is leaking based on a unbalanced current between a phase line and a neutral line of the power supply line, act when the power supply line is leaking, and transmit a leakage signal to the power distribution diagnosis module (10);
the lightning protector (23) is configured to connect to the power supply line, act when a surge voltage of the power supply line exceeds a preset voltage, and transmit a surge signal to the power distribution diagnosis module (10); and
the air switch (24) is configured to connect to the power supply line, act when a current flowing through the power supply line exceeds a preset current, and transmit an overcurrent signal to the power distribution diagnosis module (10).

4. The intelligent power distribution device according to claim 1, wherein the fixing mechanism (60) comprises: a mechanism body (61), a fixed clamping piece (62) and a movable clamping piece (63), wherein
the mechanism body (61) is arranged on the back of the power distribution diagnosis module (10);
the fixed clamping piece (62) and the movable clamping piece (63) both are arranged on a side of the mechanism body (61) remote from the power distribution diagnosis module (10), and are arranged along a length direction of the first guide rail (40); and
the movable clamping piece (63) is configured to move back and forth between a first position and a second position, wherein:
in a case that the movable clamping piece (63) is at the first position, a distance between the movable clamping piece (63) and the fixed clamping piece (62) is not less than a width of the first guide rail (40); and
in a case that the movable clamping piece (63) is at the second position, a distance between the movable clamping piece (63) and the fixed clamping piece (62) is smaller than the width of the first guide rail (40), wherein the movable clamping piece (63) bears force along a width direction of the first guide rail (40) and remains motionless.

5. The intelligent power distribution device according to claim 4, wherein the fixing mechanism (60) further comprises: a guide rod (64), an elastic member (65), a connection block (66) and a sliding block (67), wherein:
the mechanism body (61) comprises a first limiting part (611) and a second limiting part (612) that are arranged along a length direction of the first guide rail (40), a cavity structure (613) is formed between the first limiting part (611) and the second limiting part (612), a first slot (614) is formed on the side of the mechanism body (61) remote from the power distribution diagnosis module (10), the first slot (614) is in communication with the cavity structure (613), and the second limiting part (612) is provided with a second slot (615) through which the cavity structure (613) is in communication with the outside of the mechanism body (61);
the movable clamping piece (63) is provided with an extension part (631) passing through the first slot (614), the extension part (631) is moveable in the first slot (614) along the width direction of the first guide rail (40), the extension part (631) is provided with a through hole along the width direction of the first guide rail (40), and the through hole is arranged in the cavity structure (613);
the guide rod (64) is arranged between the first limiting part (611) and the second limiting part 612 and passes through the through hole, and the elastic member (65) is arranged along the guide rod (64) and between the first limiting part (611) and the extension part (631);
the connection block (66) is arranged in the cavity structure (613) and is fixed to the extension part (631), and a side of the connection block (66) close to the second slot (615) has a first boss structure with a first inclined surface (661); and
the sliding block (67) is arranged in the second slot (615) and is configured to slide, in the second slot (615), back and forth between a third position and a fourth position along a direction perpendicular to the width direction of the first guide rail (40); a side of the sliding block (67) close to the connection block (66) has a second boss structure with a second inclined surface (671), and the first inclined surface (661) fits the second inclined surface (671); and the first inclined surface (661) and the second inclined surface (671) slope with respect to the direction along which the sliding block (67) slides, wherein:
in a case that the sliding block (67) is at the third position, an end of the first boss structure is at bottom of the second boss structure, and the movable clamping piece (63) is at the first position; and
in a case that the sliding block (67) is at the fourth position, the end of the first boss structure is on top of the second boss structure and is attached to the top of the second boss structure, and the movable clamping piece (63) is at the second position.

6. The intelligent power distribution device according to claim 5, wherein the number of the guide rod (64), the number of the elastic member (65) and the number of the through hole each are more than one and are equal; and the more than one guide rod (64), the more than one elastic member (65), and the more than one through hole are distributed along the length direction of the first guide rail (40).

7. The intelligent power distribution device according to claim 5, wherein the fixing mechanism (60) further comprises a dial block (68), the dial block (68) is fixedly connected to the sliding block (67), and at least part of the dial block (68) protrudes from the mechanism body (61).

8. The intelligent power distribution device according to claim 1, wherein the number of the fixing mechanism (60) is more than one, and the more than one fixing mechanism (60) is arranged on the back of the power distribution diagnosis module (10) along a length direction of the first guide rail (40).

9. A mounting apparatus for a power distribution device, comprising:
a mounting frame;
a first guide rail;
a second guide rail; and
a fixing mechanism, wherein the fixing mechanism is configured to fix a power distribution module on one or more of the first guide rail and the second guide rail.

10. The mounting apparatus according to claim 9, wherein the fixing mechanism comprises:
a mechanism body configured to be arranged on the back of the power distribution module, wherein the mechanism body comprises a fixed clamping piece and a movable clamping piece, wherein:
the fixed clamping piece and the movable clamping piece both are arranged on a side of the mechanism body opposite the power distribution module, and are arranged along a length direction of the first guide rail; and
the movable clamping piece is configured to move between a first position and a second position.

11. The mounting apparatus according to claim 10, wherein:
when the movable clamping piece is at the first position, a distance between the movable clamping piece and the fixed clamping piece is not less than a width of the first guide rail; and
when the movable clamping piece is at the second position, a distance between the movable clamping piece and the fixed clamping piece is smaller than the width of the first guide rail, wherein the movable clamping piece is configured to bear a force along a width direction of the first guide rail and is configured to remain motionless.

12. The mounting apparatus according to claim 10, wherein:
the mechanism body comprises a first limiting part and a second limiting part that are arranged along a length direction of the first guide rail, a cavity structure between the first limiting part and the second limiting part, a first slot on the side of the mechanism body opposite the power distribution module, the first slot in communication with the cavity structure, and wherein the second limiting part includes a second slot through which the cavity structure is in communication with the outside of the mechanism body;
the movable clamping piece includes an extension part passing through the first slot, the extension part is moveable in the first slot along the width direction of the first guide rail, the extension part includes a through hole along the width direction of the first guide rail, and the through hole is arranged in the cavity structure.

13. The mounting apparatus according to claim 12, wherein the fixing mechanism further comprises:
a guide rod;
an elastic member;
a connection block; and
a sliding block.

14. The mounting apparatus according to claim 13, wherein:
the guide rod is arranged between the first limiting part and the second limiting part and passes through the through hole, and the elastic member is arranged along the guide rod and between the first limiting part and the extension part;
the connection block is arranged in the cavity structure and is fixed to the extension part, and a side of the connection block close to the second slot has a first boss structure with a first inclined surface; and
the sliding block is arranged in the second slot and is configured to slide, in the second slot, between a third position and a fourth position along a direction perpendicular to the width direction of the first guide rail; a side of the sliding block close to the connection block has a second boss structure with a second inclined surface, and the first inclined surface fits the second inclined surface; and the first inclined surface and the second inclined surface slope with respect to the direction along which the sliding block is configured to slide.

15. The mounting apparatus according to claim 14, wherein:
when the sliding block is at the third position, an end of the first boss structure is at bottom of the second boss structure, and the movable clamping piece is at the first position; and
when the sliding block is at the fourth position, the end of the first boss structure is on top of the second boss structure, and the movable clamping piece is at the second position.

16. The mounting apparatus according to claim 13, wherein the fixing mechanism further comprises a dial block, the dial block is connected to the sliding block, and at least part of the dial block protrudes from the mechanism body.

17. An intelligent power distribution device, comprising:
a power distribution diagnosis module; and
a power distribution monitoring module, wherein the power distribution monitoring module comprises a power measuring and controlling instrument;
wherein:
the power measuring and controlling instrument is configured to connect to a power supply line to be protected, and measure power data of the power supply line, wherein the power data comprises a current, a voltage, and one or more of active power, reactive power, apparent power, a power factor, a power supply frequency, a peak voltage, a peak current, and power harmonics; and
the power distribution diagnosis module is configured to be connected to the power measuring and controlling instrument, is configured to analyze the power data uploaded by the power measuring and controlling instrument, and is configured to protect the power supply line in response to a determination that the power supply line requires protection.

18. The intelligent power distribution device according to claim 17, wherein the power distribution diagnosis module comprises a wireless communication unit, wherein the wireless communication unit is configured to:
upload the power data to a cloud platform;
instruct the cloud platform to iteratively update, based on the power data uploaded by the wireless communication unit, a data operating characteristic database; and
receive the updated data operating characteristic database transmitted by the cloud platform.

19. The intelligent power distribution device according to claim 17, wherein the power distribution monitoring module further comprises one or more of a leakage protector, a lightning protector, and an air switch.

20. The intelligent power distribution device according to claim 19, wherein:
the leakage protector is configured to:
be connected to the power supply line;
determine whether the power supply line is leaking based on a unbalanced current between a phase line and a neutral line of the power supply line;
act, in response to a determination that the power supply line is leaking; and
transmit a leakage signal to the power distribution diagnosis module;
the lightning protector is configured to:
be connected to the power supply line;
act, in response to a determination that a surge voltage of the power supply line exceeds a preset voltage; and
transmit a surge signal to the power distribution diagnosis module; and
the air switch is configured to:
to be connected to the power supply line;
act, in response to a determination that a current flowing through the power supply line exceeds a preset current; and
transmit an overcurrent signal to the power distribution diagnosis module.
